(19) United States
(12) Patent Application Publication
(10) Pub. No.: US 2011/0117741 A1
(43) Pub. Date: May 19, 2011

(54) Method of fabricating SOI wafer

(75) Inventors: Tomohiro Okamura, Miyagi (JP); Masao Okihara, Miyagi (JP)

(73) Assignee: OKI SEMICONDUCTOR CO., LTD., Tokyo (JP)

(21) Appl. No.: 12/926,123

(22) Filed: Oct. 27, 2010

(30) Foreign Application Priority Data
Nov. 13, 2009 (JP) 2009-260321

(51) Int. Cl. H01L 21/302

(52) U.S. Cl. 438/694; 257/E21.214

(57) ABSTRACT

There is provided a method of fabricating an SOI wafer, the method including: a) preparing a bonded SOI substrate that has a buried oxide layer and an SOI layer formed in this sequence on a circular plate shaped support, and at a peripheral edge portion of the support substrate, has a silicon island region in which the SOI layer is not well formed with scattered defective silicon layer; b) etching a silicon island region defective silicon layer to remove the defective silicon layer scattered in the silicon island region by dry etching; and c) etching a silicon island region buried oxide layer to remove the buried oxide layer in the silicon island region by wet etching.

### CROSS-REFERENCE TO RELATED APPLICATION

This application is based on and claims priority under 35 USC 119 from Japanese Patent Application No. 2009-260321 filed on Nov. 13, 2009, the disclosure of which is incorporated by reference herein.

### BACKGROUND

1. Technical Field

The present invention relates to a method of fabricating an SOI wafer that suppresses generation of fragments (particles) when performing wet etching to a buried oxide layer (BOX layer) in a bonded wafer.

2. Related Art

There is a proposal to form a trench for inter-element isolation to an SOI substrate (see, for example, Japanese Patent Application Laid-Open (JP-A) No. 5-109882). When forming a trench, an oxide film is formed on a bonded SOI substrate surface, using a CVD method or the like, and an opening portion is formed in the oxide film by photolithographic processing in a region corresponding to a trench forming region, and the oxide film employed as a mask for etching. The trench forming region exposed through the oxide film is selectively etched by Reactive Ion Etching (RIE) or the like, and a trench is formed with, for example, a depth dimension of about 10 to 15 μm.

A method is described (see, for example, JP-A No. 10-83986) of making the thickness of a buried oxide layer thicker when forming a trench in a bonded SOI substrate for inter-element isolation, in order to suppress generation of black silicon generated at the support substrate and to suppress dust generation from the edge.

Generally in a bonded SOI substrate fabrication method, when forming a Silicon On Insulator (SOS) layer on a buried oxide layer (BOX layer) of a support substrate formed with a BOX layer, it is known that the SOI layer does not form well at the peripheral edge portion of a circular plate shaped support substrate (a region up to about 1 mm to 2 mm from the edge of the support substrate), with this resulting in a region in which a scattered silicon layer is present (a silicon island region),

Specifically, as shown in FIG. 1A to FIG. 1C, a SOI layer 6 is well formed at a central portion of a circular plate shaped support substrate 2, with a uniform SOI layer 6. However, at a peripheral edge portion of the circular plate shaped support substrate 2, due to poor formation of the SOI layer 6, the SOI layer 6 is not formed evenly, with scattered defective silicon layer 6′ present in a state like that of islands sticking out of a sea (see FIG. 1A and FIG. 1C). There is a silicon island region 8 scattered with the defective silicon layer 6′.

If oxide film wet etching processing is performed to the BOX layer 4 in the above state in which the defective silicon layer 6′ remains in the silicon island region 8, a problem arises from the generation of fragments (particles) due to the defective silicon layer 6′ shown in the magnified view of FIG. 1A and in FIG. 1C lifting off.

Furthermore, if dry etching processing for oxide film removal is performed to this region, the defective silicon layer 6′ shown in the magnified view of FIG. 1A and FIG. 1C acts as an etching mask, and since this leads to unintentional steps being formed, this further promotes generation of the above fragments (particles).

### SUMMARY

An object of the present invention is to suppress generation of fragments (particles) even in cases in which there is a process of performing wet etching processing to a buried oxide layer (BOX layer) in a silicon island region.

The above issue is addressed by the present invention below.

A first aspect of the present invention provides a method of fabricating an SOI wafer, the method including:

a) preparing a bonded SOI substrate that has a buried oxide layer and an SOI layer formed in this sequence on a circular plate shaped support, and at a peripheral edge portion of the support substrate, has a silicon island region in which the SOI layer is not well formed with scattered defective silicon layer;

b) etching a silicon island region defective silicon layer to remove the defective silicon layer scattered in the silicon island region by dry etching; and

c) etching a silicon island region buried oxide layer to remove the buried oxide layer in the silicon island region by wet etching.

The method of fabricating an SOI wafer according to the first aspect of the present invention includes the silicon island region defective silicon layer etching process that removes defective silicon layer scattered in the silicon island region by dry etching processing prior to the silicon island region buried oxide layer etching process. Accordingly, when wet etching processing is performed to the buried oxide layer (BOX layer) 4 in the silicon island region 8, as shown in the magnified view of FIG. 1A and in FIG. 1C, since there is none of the defective silicon layer 6′, the source of fragment (particle) generation, generation of the fragments (particles) is suppressed.

A second aspect of the present invention provides the SOI wafer fabrication method of the first aspect, further including, after the preparing of the bonded SOI substrate and prior to the etching of the silicon island region buried oxide layer:

forming a masking insulator film on the SOI layer and the silicon island region of the bonded SOI substrate;

coating a resist material onto the masking insulator film, and removing the resist material that has been coated onto the silicon island region by edge rinsing;

patterning a resist material by removing resist material at locations corresponding to locations where a trench is to be formed in the SOI layer;

forming a masking insulator film opening by etching the masking insulator film using the resist material as a mask to form an opening portion in the masking insulator film for forming the trench in the SOI layer, and removing the masking insulator film over the silicon island region;

separating a resist material; and

forming a combined SOI layer trench by dry etching silicon island region defective silicon layer using the masking insulator film formed with opening portions as a mask to form the trench in the SOI layer, and removing the defective silicon layer.

In the method of fabricating an SOI wafer according to the second aspect of the present invention, the process of removing the defective silicon layer in the silicon island region by dry etching is performed by the dry etching for forming the trench in the SOI layer. More specifically, as shown in FIG. 2, the masking insulator film is formed over the SOI layer 6 and over the silicon island region 8 of the bonded SOI substrate, and the resist material is further coated on the masking insulator film. When this is performed, the resist material coated over the silicon island region is removed by edge rinsing (for example, as shown in FIG. 2, by edge rinsing to remove resist material by edge rinsing a portion of width 10′), such that a state is achieved in which there is no resist material present above the silicon island region 8. The resist material is then patterned, the resist material is removed in locations corresponding to the locations where a trench is to be formed in the SOI layer, and the masking insulator film is etched with the resist material acting as a mask. An opening portion for forming the trench in the SOI layer is thereby formed in the masking insulator film, and the masking insulator film on the silicon island region is also removed, to achieve a state in which the defective silicon layer scattered in the silicon island region is exposed. The resist material is then separated, and through the combined SOI layer trench forming and silicon island region defective silicon layer etching process, the trench is formed in the SOI layer, and the defective silicon layer scattered in the silicon island region is removed before moving on to the silicon island region buried oxide layer etching process.

By performing the process to remove defective silicon layer in the silicon island region by dry etching during the dry etching to form the trench in the SOI layer, generation of fragments (particles) is suppressed without increasing the number of processes.

A third aspect of the present invention provides the SOI wafer fabrication method of the second aspect, further including, light-exposuring a silicon island region after the forming of the masking insulator film opening and before the forming of the combined SOI layer trench and the etching of the silicon island region defective silicon layer.

In SOI wafer fabrication, sometimes complete element isolation is performed and sometimes complete element isolation is not performed. For example, for an SOI wafer such as one employed in a fully-depleted SOI device, as shown in FIG. 3, generally element isolation is by removing the full thickness of the SOI layer 6 and forming a trench of the same thickness as the SOI layer 6 to perform complete element isolation. However, for an SOI wafer employed in an SOI device of high withstand voltage, as shown in FIG. 4, generally element isolation is by removing only part of the thickness of the SOI layer 6 and forming a trench with a thinner thickness than that of the SOI layer 6, such that complete element isolation is not performed. However, even for an SOI wafer in which complete element isolation is not performed, there is sometimes defective silicon layer 6′ present in the silicon island region of similar thickness.

In such cases, the SOI wafer fabrication method according to the third aspect of the present invention has a process in which light-exposure of the defective silicon layer scattered in the silicon island region is performed, and there is excellent removal of the light-exposed defective silicon layer by the dry etching processing of the combined SOI layer trench forming and silicon island region defective silicon layer etching process.

According to the present invention, a method of fabricating an SOI wafer is provided that suppresses generation of fragments (particles) even in cases in which wet etching processing is performed to the buried oxide layer (BOX layer) in the silicon island region.

### BRIEF DESCRIPTION OF THE DRAWINGS

Exemplary embodiments of the present invention will be described in detail based on the following figures, wherein:

FIG. 1A to FIG. 1C are schematic diagrams for explaining a silicon island region in a bonded SOI substrate;

FIG. 2 is a schematic diagram for explaining the width for resist material removal by edge rinsing in a resist material coating process;

FIG. 3 is a schematic cross-section showing an example of a bonded SOI substrate on which complete element isolation has been performed; and

FIG. 4 is a schematic cross-section showing an example of a bonded SOI substrate on which complete element isolation is not performed.

### DETAILED DESCRIPTION

A method of fabricating an SOI wafer according to the present invention includes: a bonded SOI substrate preparing step in which a bonded SOI substrate is prepared that has a buried oxide layer and an SOI layer formed in this sequence on a circular plate shaped support, and at a peripheral edge portion of the support substrate, has a silicon island region in which the SOI layer is not well formed with scattered defective silicon layer; a silicon island region defective silicon layer etching process in which the defective silicon layer scattered in the silicon island region is removed by dry etching; and a silicon island region buried oxide layer etching process in which the buried oxide layer in the silicon island region is removed by wet etching.

Note that the above silicon island region defective silicon layer etching process may be by way of a dedicated etching process for removing defective silicon layer in the silicon island region, or may be by way of performing a combined process with a SOI layer etching process such that both processes are performed in a single dry etching process. Examples of the above SOI layer etching process include, for example, a dry etching process for forming a trench in the SOI layer, and the like.

Detailed explanation follows regarding a case in which a combination of both a silicon island region defective silicon layer etching process and an etching process of the SOI layer are performed by a single occasion of dry etching process, namely, a case in which an SOI layer trenching process and silicon island region defective silicon layer etching process are performed.

Bonded SOI Substrate Preparation Process

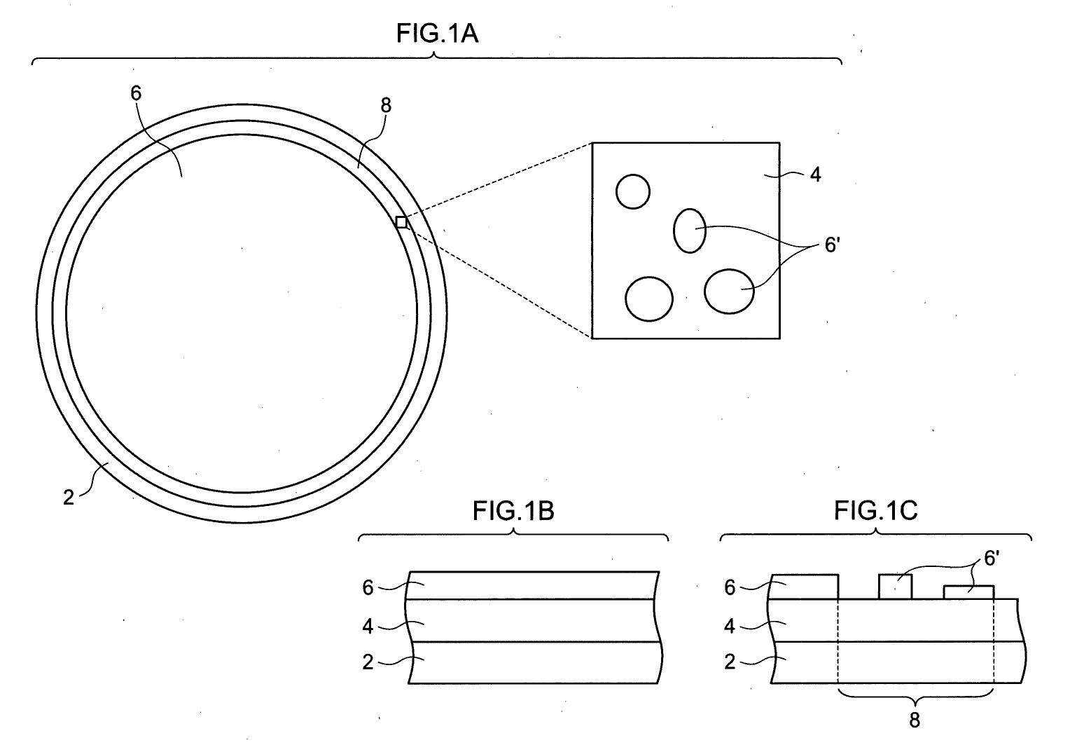

First, a bonded SOI substrate is prepared that has a buried oxide layer and an SOI layer formed in this sequence on a circular plate shaped support, and at a peripheral edge portion of the support substrate, has a silicon island region in which the SOI layer is not well formed with scattered defective silicon layer. Specifically, a bonded silicon on insulator (SOI) substrate is prepared as shown in FIG. 1. This bonded SOI substrate in one including a support substrate 2, a buried oxide layer (BOX layer) 4 formed on the surface of the support substrate 2 as a thermally oxidized layer buried in the bonded SOI substrate, and a bonded SOI layer 6 disposed on the main face side of the bonded SOI substrate with the BOX layer 4 in an interposed state between the bonded SOI layer 6 and the main face.

Brief explanation follows regarding fabricating the bonded SOI substrate. First, a thermally oxidized layer that will become a buried oxide layer (BOX) layer is formed on the main surface of a support substrate that acts as the base. An SOI layer that will become the element forming side is also prepared. Then mirrored faces of the BOX layer and the SOI layer are bonded together by annealing in a clean atmosphere using a known direct bonding method. Note that after bonding the above SOI layer may be thinned by grinding from the front face side, and the peripheral edge portion may also be ground from the perspective of preventing edge defects. Masking tape is then used to cover both the top face and the back surface of the bonded support substrate and SOI layer with the BOX layer interposed therebetween, and the outer peripheral portion of the SOI layer may then be removed by wet etching with a chemical liquid, and the front surface of the silicon may also be finished by polishing. A bonded SOI substrate having an SOI layer of the desired thickness is thus obtained.

Note that in the above bonded SOI substrate fabrication method, a silicon island region is formed with scattered defective silicon layer 6′.

Masking Insulator film Forming Process

A masking insulator film is then formed on the SOI layer and silicon island region of the bonded SOI substrate.

A silicon nitride film and/or a masking oxide film is deposited as a masking insulator film on the top surface side of the bonded SOI substrate, namely on the side on which the SOI layer 6 and the silicon island region 8 have been formed, by a CVD method or the like. Note that a masking oxide film may be formed by thermal oxidization.

Resist Material Coating Process

Next, a resist material is coated onto the masking insulator film, and the resist material that has been coated over the silicon island region is removed by edge rinsing.

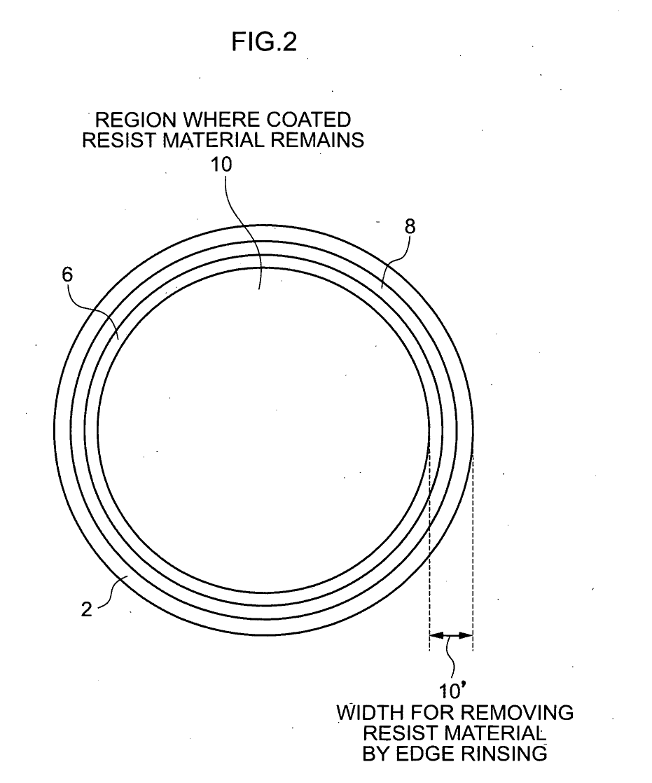

The resist material is a photoresist and is coated onto the surface of the SOI substrate on the side formed with the masking insulator film. When doing so, photoresist is coated across the entire surface of the bonded SOI substrate by dripping a photoresist liquid thereon using spin coating. Either during coating or directly after coating, the resist material that has been coated over the silicon island region is removed by edge rinsing, as shown in FIG. 2, thereby achieving a state in which there is no resist material present above the silicon island region 8. Note that in order that no resist material remains above the silicon island region 8, edge rinsing is preferably performed for a region extending to just inside of the portion where the silicon island region 8 is present (in FIG. 2 edge rinsing is such that resist material is removed by edge rinsing from a portion of width 10′). By performing the edge rinse processing thus, a state is achieved in which there is no photoresist above the silicon island region at the peripheral edge portion of the bonded SOI substrate.

Note that edge rinse processing is rinse-off processing in which a developer liquid is dripped onto the outer peripheral portion of the photoresist immediately after coating. Photoresist that has flowed around the peripheral edge portion to the back face side is thereby also removed, achieving an improvement in the processing precision for subsequent processes.

Resist Material Patterning Process

Next, the resist material is patterned and the resist material is removed at locations corresponding to the locations where trench(es) is/are to be formed in the SOI layer.

Specifically, a specific pattern is formed in the photoresist by employing a mask during light-exposure corresponding to the portion where trench etching processing is to performed, followed by developing the photoresist. The pattern of the photoresist formed thereby is a pattern for forming opening portion(s) in the masking insulator film in the next process.

Masking Insulator film Opening Portion Forming Process

Next, the masking insulator film is etched with the resist material acting as a mask, and an opening portion is formed in the masking insulator film for forming a trench in the SOI layer, and the masking insulator film is also removed above the silicon island region.

The opening portion may be formed at a trench forming portion in the masking insulator film by performing dry etching processing with a mixed gas of, for example, CF₄, CHF₃, Ar or the like. The masking insulator film is also removed at the peripheral edge portion (a region including the silicon island region) of the bonded SOI substrate from which the resist material has been removed by edge rinse processing in the resist material coating process, thereby exposing the defective silicon layer 6′ in the silicon island region.

Resist Material Separation Process

After processing to pattern the masking insulator film, the photoresist remaining on the bonded SOI substrate is separated off. A state is thereby achieved in which the opening portion for use in trench etching is formed in the masking insulator film on the bonded SOI substrate. At the peripheral edge portion of the bonded SOI substrate, the masking insulator film is then removed by etching, to achieve a state in which the silicon island region is exposed.

Combined SOI Layer Trench Forming and Silicon Island Region Defective Silicon Layer Etching Process

Next, using the masking insulator film formed with the opening portion as a mask, the SOI layer and the defective silicon layer scattered in the silicon island region are dry etched, so as to both form a trench in the SOI layer and remove the defective silicon layer.

Specifically, silicon exposed through the opening portion formed in the masking insulator film is selectively dry etched by Reactive Ion Etching (RIE) processing employing a reaction gas of, for example, a mixture of HBr, SiF₄, SF₆, He/O₂ or the like (trench etching). Thereby, silicon is etched of the thickness down to the SOI layer and a trench is formed. At the peripheral edge portion (a region-including the silicon island region) of the bonded SOI substrate where the masking insulator film has been removed by etching processing in the above masking insulator film opening forming process, the defective silicon layer 6′ in the silicon island region is removed by the above Reactive Ion Etching (RIE) processing.

Silicon Island Region Buried Oxide Layer Etching Process

Then, after removing reaction products deposited on the inside walls of the trench by using an etchant such as, for example, HF or the like, thermal oxidation processing is performed to form an oxidized film on the silicon surface within the trench. The trench is embedded with an oxidized layer using a method such as, for example, HDP-CVD or the like (shallow Trench Isolation (STI)), and then flattening is performed by Chemical Mechanical Polishing (CMP).

After the STI embedded portion has been flattened by the above CMP, the STI height is adjusted using an etchant such as, for example, HF or the like. Phosphoric acid is then employed to remove the above silicon nitride film, and the masking insulator film is removed using an etchant, such as HF or the like.

Through the above processes, a multi-segmented silicon region is formed in which the chip forming regions on the bonded SOI substrate are isolated from each other.

Explanation follows regarding a second exemplary embodiment having a silicon island region light-exposing process performed by light-exposure onto the defective silicon layer scattered in the silicon island region, performed after the masking insulator film opening forming process and before the combined SOI layer trench forming and silicon island region defective silicon layer etching process.

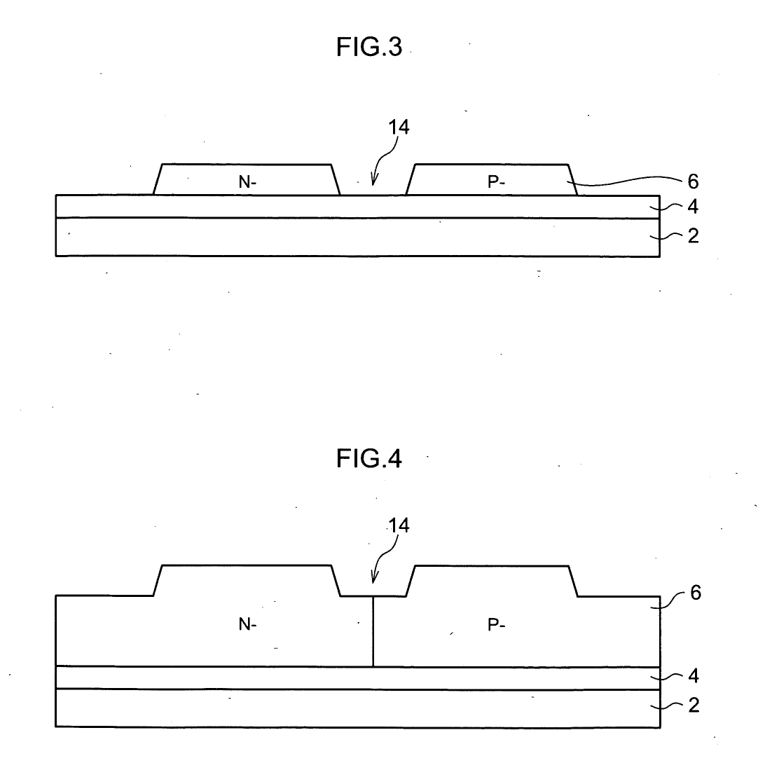

In SOI wafer fabrication, sometimes complete element isolation is performed and sometimes complete element isolation is not performed. For example, for an SOI wafer employed in a fully-depleted SOI device, as shown in FIG. 3, generally element isolation is by removing the full thickness of the SOI layer 6 and forming a trench 14 of the same thickness as the SOI layer 6 to perform complete element isolation. However, for an SOI wafer employed in an SOI device of high withstand voltage, as shown in FIG. 4, generally element isolation is by removing only part of the thickness of the SOI layer 6 and forming the trench 14 with a thinner thickness than that of the SOI layer 6, such that complete element isolation is not performed. However, even for an SOI wafer in which complete element isolation is not performed, there is sometimes defective silicon layer 6′ in the silicon island region of similar thickness.

In particular, as described above, in cases where complete element isolation is not performed, preferably there is a process of performing light-exposure to the defective silicon layer scattered in the silicon island region. There is excellent removal of the light-exposed defective silicon layer by dry etching processing in the combined SOI layer trench forming and silicon island region defective silicon layer etching process.

Note that in the above light-exposure, preferably light-exposure is performed to a region up to just inside the portion where the silicon island region 8 is present (a width 10′ from which resist material is removed by edge rinsing shown in FIG. 2), from the perspective of ensuring illumination of the silicon island region. However, preferably light-exposure is not performed to regions any further inside than this.

What is claimed is:

1. A method of fabricating an SOI wafer, the method comprising:
a) preparing a bonded SOI substrate that has a buried oxide layer and an SOI layer formed in this sequence on a circular plate shaped support, and at a peripheral edge portion of the support substrate, has a silicon island region in which the SOI layer is not well formed with scattered defective silicon layer;
b) etching a silicon island region defective silicon layer to remove the defective silicon layer scattered in the silicon island region by dry etching; and
c) etching a silicon island region buried oxide layer to remove the buried oxide layer in the silicon island region by wet etching.

2. The SOI wafer-fabrication method of claim 1, further comprising, after the preparing of the bonded SOI substrate and prior to the etching of the silicon island region buried oxide layer:
forming a masking insulator film on the SOI layer and the silicon island region of the bonded SOI substrate;
coating a resist material onto the masking insulator film, and removing the resist material that has been coated onto the silicon island region by edge rinsing;
patterning a resist material by removing resist material at locations corresponding to locations where a trench is to be formed in the SOI layer;
forming a masking insulator film opening by etching the masking insulator film using the resist material as a mask to form an opening portion in the masking insulator film for forming the trench in the SOI layer, and removing the masking insulator film over the silicon island region;
separating a resist material; and
forming a combined SOI layer trench by dry etching silicon island region defective silicon layer using the masking insulator film formed with opening portions as a mask to form the trench in the SOI layer, and removing the defective silicon layer.

3. The SOI wafer fabrication method of claim 2, further comprising, light-exposuring a silicon island region after the forming of the masking insulator film opening and before the forming of the combined SOI layer trench and the etching of the silicon island region defective silicon layer.
